(19) United States
(12) Patent Application Publication
(10) Pub. No.: US 2026/0098756 A1
(43) Pub. Date: Apr. 9, 2026

(54) MICROFABRICATED DEVICE WITH TUNABLE SPECTRAL EMISSION

(71) Applicant: Raytheon Company, Tewksbury, MA (US)

(72) Inventors: Andrew C. McClung, Florence, MA (US); Joseph V. Mantese, Ellington, CT (US); Soumalya Sarkar, Manchester, CT (US); Sudeepta Mondal, Manchester, CT (US)

(21) Appl. No.: 18/908,425

(22) Filed: Oct. 7, 2024

(51) Int. Cl. G01J 3/02; H10N 30/20; H10N 30/853

(52) U.S. Cl. CPC G01J 3/0202; G01J 3/021; H10N 30/2047; H10N 30/853; G01J 3/0256

(57) ABSTRACT

An apparatus may include a piezoelectric membrane, a metal layer, at least one spacer, and a reflector. The piezoelectric membrane can be configured to output light with a spectral feature. The metal layer can be disposed on a surface of the piezoelectric membrane. The at least one spacer can be disposed on the piezoelectric membrane. The reflector can be disposed on an opposite side of the at least one spacer from the piezoelectric membrane. The metal layer can be configured to actuate the piezoelectric membrane to adjust the spectral feature of the light based on a control voltage.

### TECHNICAL FIELD

This disclosure relates generally to microfabricated devices and processes. More specifically, this disclosure relates to a microfabricated device with a tunable spectral emission.

### BACKGROUND

Tunable infrared emitters are useful for spectroscopy, which has many applications. Thermal emitters depend on spectral emissivity, which is typically broadband. Unfortunately, spectroscopic instruments that employ broadband sources typically require additional components to obtain spectral data. Often times, these instruments are large, heavy, and expensive.

### SUMMARY

This disclosure provides a microfabricated device with a tunable spectral emission.

In some examples, an apparatus may include a piezoelectric membrane, a metal layer, at least one spacer, and a reflector. The piezoelectric membrane can be configured to output light with a spectral feature. The metal layer can be disposed on a surface of the piezoelectric membrane. The at least one spacer can be disposed on the piezoelectric membrane. The reflector can be disposed on an opposite side of the at least one spacer from the piezoelectric membrane. The metal layer can be configured to actuate the piezoelectric membrane to adjust the spectral feature of the light based on a control voltage.

Any single one or any combination of the following features may be used with the above examples. A geometry, a thickness, and an electrical actuation of the piezoelectric layer can be determined to optimize the spectral feature of the light emitted. The metal layer can include multiple electrodes, and a pattern for metal electrodes can be determined to optimize the spectral feature of the light emitted by the piezoelectric membrane. An initial distance between the metal layer and the reflector can be based on the spectral feature of the light emitted by the piezoelectric membrane. The piezoelectric membrane can include at least one of aluminum scandium nitride, lithium tantalate, and lithium nitride. The metal layer and the reflector can include at least one of platinum, palladium, and nickel. The metal layer and the reflector may not include gold.

In other examples, an apparatus may include an array of thermal devices and one or more processors. Each of the thermal devices may include a piezoelectric membrane, a metal layer, at least one spacer, and a reflector. The piezoelectric membrane can be configured to output light with a spectral feature. The metal layer can be disposed on a surface of the piezoelectric membrane. The metal layer can be configured to actuate the piezoelectric membrane to adjust the spectral feature of the light based on a control voltage. The at least one spacer can be disposed on the piezoelectric membrane. The reflector can be disposed on an opposite side of the at least one spacer from the piezoelectric membrane. The one or more processors may be configured to regulate, for each thermal device, the control voltage applied to the metal layer for each thermal device.

Any single one or any combination of the following features may be used with the above examples. For each thermal device, a geometry, a thickness, and an electrical actuation of the piezoelectric layer can be determined to optimize the spectral feature of the light emitted. For each thermal device, the metal layer can include multiple electrodes, and a pattern for metal electrodes of the metal layer can be determined to optimize the spectral feature of the light emitted by the piezoelectric membrane. For each thermal device, an initial distance between the metal layer and the reflector can be based on the spectral feature of the light emitted by the piezoelectric membrane. For each thermal device, the piezoelectric membrane can include at least one of aluminum scandium nitride, lithium tantalate, and lithium nitride. For each thermal device, the metal layer and the reflector can include at least one of platinum, palladium, and nickel. For each thermal device, the metal layer and the reflector may not include gold.

In still other examples, a method may include disposing a metal layer on a surface of a piezoelectric membrane configured to output a light with a spectral feature. The method may also include disposing at least one spacer extending from the piezoelectric membrane. The method may further include disposing a reflector on an opposite side of the at least one spacer from the piezoelectric membrane. The metal layer can be configured to, based on a control voltage, actuate the piezoelectric membrane to adjust the spectral feature of the light.

Any single one or any combination of the following features may be used with the above examples. The method may include determining a geometry, a thickness, and an electrical actuation of the piezoelectric layer to optimize the spectral feature of the light emitted. The method may include determining a pattern for metal electrodes of the metal layer to optimize the spectral feature of the light emitted by the piezoelectric membrane. An initial distance between the metal layer and the reflector can be based on the spectral feature of the light emitted by the piezoelectric membrane. The piezoelectric membrane can include at least one of aluminum scandium nitride, lithium tantalate, and lithium nitride. The metal layer and the reflector can include at least one of platinum, palladium, and nickel.

Other technical features may be readily apparent to one skilled in the art from the following figures, descriptions, and claims.

### BRIEF DESCRIPTION OF THE DRAWINGS

For a more complete understanding of this disclosure, reference is made to the following description, taken in conjunction with the accompanying drawings, in which:

FIGS. 1A and 1B illustrate an example thermal emitter in accordance with this disclosure;

FIGS. 2A and 2B illustrate example electrodes for a metal layer of the thermal emitter in accordance with this disclosure;

FIG. 3 illustrates an example throw/catch architecture using thermal emitters and thermal absorbers in accordance with this disclosure; and

FIG. 4 illustrates an example method for forming a microfabricated device with tunable spectral emission according to this disclosure.

### DETAILED DESCRIPTION

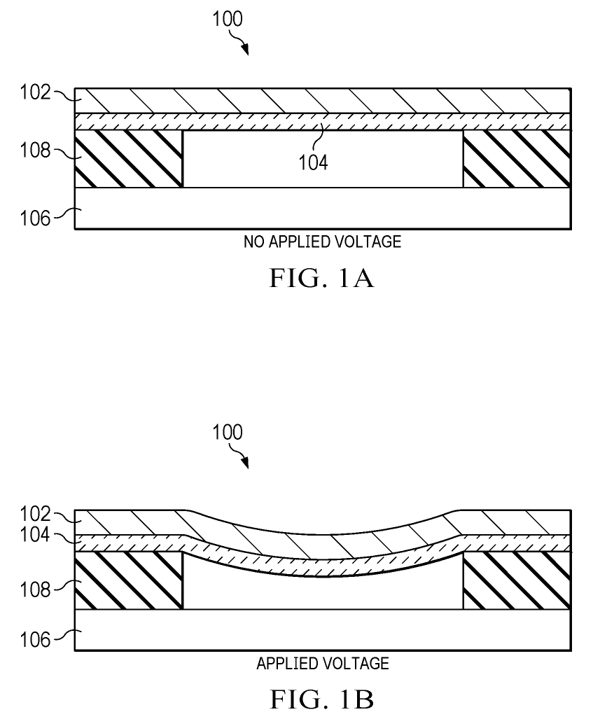

FIGS. 1A through 4, described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system.

As described above, tunable infrared emitters are useful for spectroscopy, which has many applications. Thermal emitters depend on spectral emissivity, which is typically broadband. Unfortunately, spectroscopic instruments that employ broadband sources typically require additional components to obtain spectral data. Often times, these instruments are large, heavy, and expensive. Commercial off-the-shelf (COTS) thermal emitters are broadband and have low radiance. Infrared light emitting diodes (LEDs) can have a higher radiance and narrow spectra but are often not tunable. Quantum cascade lasers are narrowband and have high radiance but are expensive. This disclosure provides for a microfabricated device with a tunable spectral emission, which (depending on the implementation) can be tunable, can be narrowband, can provide high radiance, can have lower cost, and/or can operate in extreme environments.

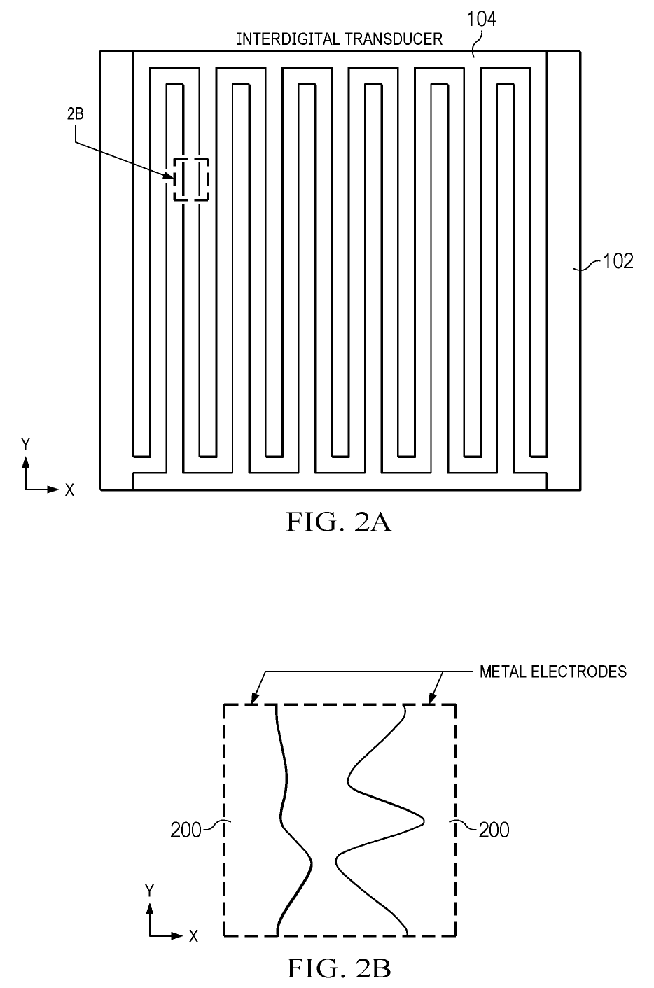

FIGS. 1A and 1B illustrate an example thermal emitter 100 in accordance with this disclosure. FIGS. 2A and 2B illustrates example electrodes 200 for a metal layer 104 of the thermal emitter 100 in accordance with this disclosure. Note that while described as a thermal emitter, the components of the thermal emitter 100 can also or alternatively be utilized as a thermal absorber, in which case light with a spectral feature is received and causes the components of the thermal absorber to output a corresponding voltage.

As shown in FIGS. 1A and 1B, the thermal emitter 100 can represent a tunable, narrowband, high-radiance, mid-infrared light source or other light source, which may be produced at low cost. The thermal emitter 100 can include a piezoelectric membrane 102, a metal layer 104, a reflector 106, and spacers 108. In some cases, the thermal emitter 100 can use both plasmonic and Fabry-Perot resonators to achieve light with a spectral feature. A control voltage applied across the metal layer 104 and the reflector 106 can cause deflection or actuation of the piezoelectric membrane 102, which can tune the spectral feature of the light.

In some embodiments, the piezoelectric membrane 102 can represent a thin film piezoelectric membrane. Also, in some embodiments, the piezoelectric membrane 102 can be made of a material compatible with high temperatures. Example materials for the piezoelectric membrane 102 can include aluminum scandium nitride (AlScN), lithium tantalate (LiTaO), and lithium nitride (Li₃N). The piezoelectric membrane 102 can be actuated to generate light with a spectral feature to be projected towards a target. When the piezoelectric membrane 102 is used in an absorber, the light with the spectral feature can be received and cause the piezoelectric membrane 102 to output a voltage across the metal layer 104 and the reflector 106. A geometry, a thickness, and an electrical actuation of the piezoelectric layer can be determined to optimize the spectral feature of the light emitted.

In some embodiments, the metal layer 104 can be formed on a surface of the piezoelectric membrane 102. The metal layer 104 can receive a control voltage that generates an electric field with the reflector 106 to cause mechanical actuation of the piezoelectric membrane 102. The actuation of the piezoelectric membrane 102 changes or tunes the spectral feature of the light. In some embodiments, the metal layer 104 can also provide a plasmonic filter. The metal layer 104 can be made of any suitable metal(s), such as platinum (Pt), palladium (Pd), or nickel (Ni). In particular embodiments, the metal layer 104 can be made of one or more materials but exclude gold.

As shown in FIGS. 2A and 2B, the metal layer 104 can be patterned for a specified geometry, thickness, and composition to optimize tuning of the spectral feature of the light. For example, the optimization of the metal layer 104 can include determining a distance between electrodes 200. The distance between electrodes 200 can be variable, and the variability can be determined based on the spectral feature of the light. In some embodiments, the design of the metal layer 104 can be determined using an artificial intelligence framework that is trained to optimize a specified spectral feature for the light.

As shown in FIGS. 1A and 1B, the reflector 106 can be positioned at a distance from the patterned metal layer 104 using the spacers 108. In some embodiments, the reflector 106 can be formed using one or more materials that do not oxidize. The reflector 106 can be made of a metal material, such as platinum, palladium, or nickel. In particular embodiments, the reflector 106 can be made of one or more materials but exclude gold. In some embodiments, the reflector 106 may be made of the same material as the metal layer 104. The reflector 106 can also be patterned to optimize the spectral feature for the light.

The spacers 108 can separate the reflector 106 from the metal layer 104. For example, the spacers 108 may be fixed to and project from the reflector 106 to the piezoelectric layer 102 or the metal layer 104. Dimensions (such as length, width, height, and spacing) of the spacers 108 can be determined based on the desired spectral feature of the light emitted by the thermal emitter 100. In some embodiments, the spacers 108 can be made from one or more dielectric materials, such as silicon nitride (SiN).

The spectral feature of the light can be tuned by applying a voltage across the metal layer 104 and the reflector 106. The voltage can cause the piezoelectric membrane 100 to actuate and adjust the spectral feature of the light.

Although FIGS. 1A through 2B illustrate an example thermal emitter 100, various changes may be made to FIGS. 1A through 2B. For example, various components in FIGS. 1A through 2B may be combined, further subdivided, replicated, omitted, or rearranged and additional components may be added according to particular needs. Also, the relative sizes, shapes, and dimensions of the thermal emitter 100 and its individual components can vary as needed or desired.

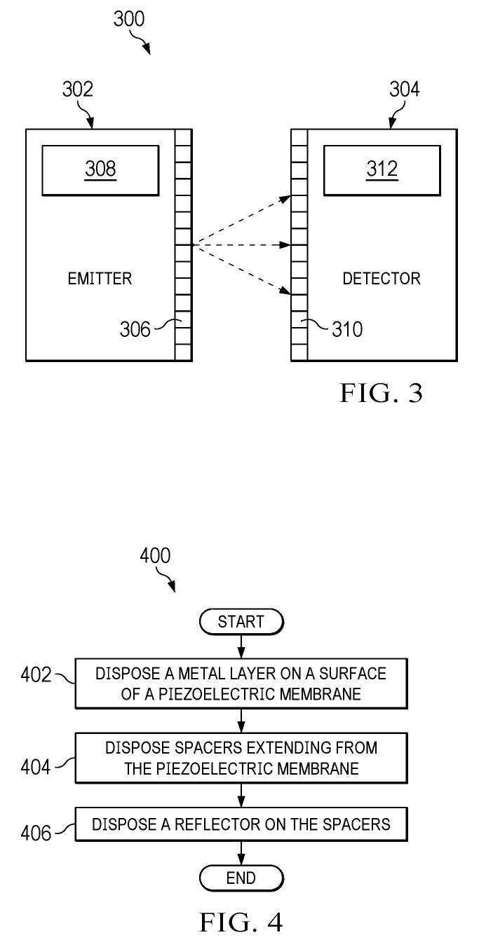

FIG. 3 illustrates an example throw/catch architecture 300 using thermal emitters 306 and thermal absorbers 310 in accordance with this disclosure. As shown in FIG. 3, the throw/catch architecture 300 can include an emitter 302 and a detector 304. The emitters 302 and the detector 304 may be referred to as thermals devices. The emitter 302 can include one or more thermal emitters 306 operably coupled to one or more emitter processors 308, and the detector 304 can include one or more thermal absorbers 310 operably coupled to one or more detector processors 312. Each of the thermal emitters 306 and thermal absorbers 310 may have the same or similar structure as the thermal emitter 100 shown in FIGS. 1A through 2.

The emitter and detector processors 308 and 312 can respectively control thermal emission of the thermal emitters 306 and thermal absorption of the thermal absorbers 310. For example, the emitter processor 308 can be used to provide a control voltage to tune the spectral feature of light for each respective thermal emitter 306 and the detector processor 312 can identify an output signal from each respective thermal absorber 310.

Although FIG. 3 illustrates one example of a throw/catch architecture 300 using thermal emitters 306 and thermal absorbers 310, various changes may be made to FIG. 3. For example, various components in FIG. 3 may be combined, further subdivided, replicated, omitted, or rearranged and additional components may be added according to particular needs.

FIG. 4 illustrates an example method 400 for forming a microfabricated device with tunable spectral emission according to this disclosure. For ease of explanation, the method 400 of FIG. 4 is described as forming the thermal emitter 100 of FIG. 1. However, the method 400 may be used with any other suitable system and any other suitable emitter or absorber.

As shown in FIG. 4, a metal layer 104 can be disposed on a surface of a piezoelectric membrane 102 at step 402. For example, the metal layer 104 can be formed on an upper or lower surface of the piezoelectric membrane 102. The metal layer 104 can be configured to generate an electric field with the reflector 106 that is used to mechanically actuate the piezoelectric membrane 102 effectively tuning the spectral feature of the light. The actuation of the piezoelectric membrane 102 can adjust the spectral feature of the light to desired specifications. The metal layer 104 can be patterned with a geometry, a thickness, and composition to optimize a spectral feature for the light. For example, a pattern of the metal layer 104 can be optimized for the spectral feature of the light emitting by the piezoelectric membrane 102. In some embodiments, the design of the metal layer 104 can be determined using an artificial intelligence framework trained to optimize the spectral feature of the light. In some cases, the metal layer 104 can also be configured to provide a plasmonic filter for the piezoelectric membrane 102.

Spacers 108 can be disposed to extend from the piezoelectric membrane 102 at step 404. A height of the spacers defines an initial distance of a gap between the piezoelectric membrane 102 and a reflector 106. The height of the spacers can be designed to optimize the spectral feature of the light emitted from the piezoelectric membrane 102. Other dimensions (e.g., length, width, and spacing) of the spacers 108 can be determined and also optimized based on the spectral feature of the light emitted by the thermal emitter 100. The spacers 108 can be made from a dielectric material, such as silicon nitride (SiN). In embodiments where the metal layer 104 is disposed on a bottom surface of the piezoelectric membrane 102, the spacers can be disposed on or extend from the metal layer 104.

A reflector 106 can be disposed on the spacers 108 in step 406. The reflector 106 can be disposed on an opposite end of the spacers 108 from the end disposed on the piezoelectric membrane 102 or the metal layer 104. The reflector 106 can be formed using one or more materials that do not oxidize. The reflector 106 can be made of a metal material, such as platinum, palladium, or nickel. In particular embodiments, the reflector 106 can be made of one or more materials excluding gold. In some embodiments, the reflector 106 may be made of the same material as the metal layer 104. The reflector 106 can also be patterned based on the spectral feature for the light.

Although FIG. 4 illustrates one example of an example method 400 for forming a microfabricated device with tunable spectral emission, various changes may be made to FIG. 4. For example, while shown as a series of steps, various steps in FIG. 4 may overlap, occur in parallel, occur in a different order, or occur any number of times.

It may be advantageous to set forth definitions of certain words and phrases used throughout this patent document. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present disclosure should not be read as implying that any particular element, step, or function is an essential or critical element that must be included in the claim scope. The scope of patented subject matter is defined only by the allowed claims. Moreover, none of the claims invokes 35 U.S.C. § 112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. An apparatus comprising:
a piezoelectric membrane configured to output light with a spectral feature;
a metal layer disposed on a surface of the piezoelectric membrane;
at least one spacer disposed on the piezoelectric membrane; and
a reflector disposed on an opposite side of the at least one spacer from the piezoelectric membrane;
wherein the metal layer is configured to actuate the piezoelectric membrane to adjust the spectral feature of the light based on a control voltage.

2. The apparatus of claim 1, wherein a geometry, a thickness, and an electrical actuation of the piezoelectric membrane are determined to optimize the spectral feature of the light emitted by the piezoelectric membrane.

3. The apparatus of claim 1, wherein:
the metal layer comprises multiple electrodes, and
a pattern for metal electrodes is determined to optimize the spectral feature of the light emitted by the piezoelectric membrane.

4. The apparatus of claim 1, wherein an initial distance between the metal layer and the reflector is based on the spectral feature of the light emitted by the piezoelectric membrane.

5. The apparatus of claim 1, wherein the piezoelectric membrane comprises at least one of aluminum scandium nitride, lithium tantalate, and lithium nitride.

6. The apparatus of claim 1, wherein the metal layer and the reflector comprise at least one of platinum, palladium, and nickel.

7. The apparatus of claim 6, wherein the metal layer and the reflector do not comprise gold.

8. An apparatus comprising:
an array of thermal devices, each thermal device comprising:
a piezoelectric membrane configured to output light with a spectral feature;
a metal layer disposed on a surface of the piezoelectric membrane, wherein the metal layer is configured to actuate the piezoelectric membrane to adjust the spectral feature of the light based on a control voltage;
at least one spacer disposed on the piezoelectric membrane; and
a reflector disposed on an opposite side of the at least one spacer from the piezoelectric membrane; and
one or more processors configured to regulate, for each thermal device, the control voltage applied to the metal layer.

9. The apparatus of claim 8, wherein, for each thermal device, a geometry, a thickness, and an electrical actuation of the piezoelectric membrane are determined to optimize the spectral feature of the light emitted by the piezoelectric membrane.

10. The apparatus of claim 8, wherein, for each thermal device:
the metal layer comprises multiple electrodes, and
a pattern for metal electrodes of the metal layer is determined to optimize the spectral feature of the light emitted by the piezoelectric membrane.

11. The apparatus of claim 8, wherein, for each thermal device, an initial distance between the metal layer and the reflector is based on the spectral feature of the light emitted by the piezoelectric membrane.

12. The apparatus of claim 8, wherein, for each thermal device, the piezoelectric membrane comprises at least one of aluminum scandium nitride, lithium tantalate, and lithium nitride.

13. The apparatus of claim 8, wherein, for each thermal device, the metal layer and the reflector comprise at least one of platinum, palladium, and nickel.

14. The apparatus of claim 13, wherein, for each thermal device, the metal layer and the reflector do not comprise gold.

15. A method comprising:
disposing a metal layer on a surface of a piezoelectric membrane configured to output a light with a spectral feature;
disposing at least one spacer extending from the piezoelectric membrane; and
disposing a reflector on an opposite side of the at least one spacer from the piezoelectric membrane,
wherein the metal layer is configured to, based on a control voltage, actuate the piezoelectric membrane to adjust the spectral feature of the light.

16. The method of claim 15, further comprising:
determining a geometry, a thickness, and an electrical actuation of the piezoelectric membrane to optimize the spectral feature of the light emitted by the piezoelectric membrane.

17. The method of claim 15, further comprising:
determining a pattern for metal electrodes of the metal layer to optimize the spectral feature of the light emitted by the piezoelectric membrane.

18. The method of claim 15, wherein an initial distance between the metal layer and the reflector is based on the spectral feature of the light emitted by the piezoelectric membrane.

19. The method of claim 15, wherein the piezoelectric membrane comprises at least one of aluminum scandium nitride, lithium tantalate, and lithium nitride.

20. The method of claim 15, wherein the metal layer and the reflector comprise at least one of platinum, palladium, and nickel.
